(19) United States
(12) Patent Application Publication
(10) Pub. No.: US 2024/0128261 A1
(43) Pub. Date: Apr. 18, 2024

(54) Passive Device Dies With Measurement Structures

(71) Applicant: Taiwan Semiconductor Manufacturing Co., Ltd., Hsinchu (TW)

(72) Inventors: Fu-Chiang KUO, Hsinchu City (TW); Yu-Hsin Fang, Kaohsiung City (TW); Min-Hsiung Chen, Hsinchu City (TW)

(73) Assignee: Taiwan Semiconductor Manufacturing Co., Ltd., Hsinchu (TW)

(21) Appl. No.: 18/128,129

(22) Filed: Mar. 29, 2023

Related U.S. Application Data
(60) Provisional application No. 63/379,477, filed on Oct. 14, 2022.

(51) Int. Cl. H01L 27/08; H01L 21/3213; H01L 21/48; H01L 21/56; H01L 21/66; H01L 23/31; H01L 23/498

(52) U.S. Cl. CPC H01L 27/0805; H01L 21/32131; H01L 21/4853; H01L 21/56; H01L 22/14; H01L 22/32; H01L 23/3171; H01L 23/49816; H01L 23/49838; H01L 28/40

(57) ABSTRACT

A structure and method for improving manufacturing yield of passive device dies are disclosed. The structure includes first and second groups of capacitors disposed on a substrate, an interconnect structure disposed on the first and second groups of capacitors, first and second bonding structures disposed on the first and second conductive lines, respectively, and first and second measurement structures connected to the first and second conductive lines, respectively, and configured to measure electrical properties of the first and second groups of capacitors, respectively. The interconnect structure includes first and second conductive line connected to the first and second groups of trench capacitors, respectively. The first bonding structure is electrically connected to the first group of capacitors and the second bonding structure is electrically isolated from the first and second groups of capacitors. The first and second measurement structures are electrically isolated from each other.

### CROSS-REFERENCE TO RELATED APPLICATION

This application claims the benefit of U.S. Provisional Patent Application No. 63/379,477, titled “Passive Device Dies with Measurement Structures,” filed Oct. 14, 2022, which is incorporated by reference in its entirety.

### BACKGROUND

With advances in semiconductor technology, there has been increasing demand for higher storage capacity, faster processing systems, higher performance, and lower costs. To meet these demands, the semiconductor industry continues to scale down the dimensions of passive semiconductor devices, such as capacitors. Such scaling down has increased the challenges of forming the passive semiconductor devices with high manufacturing yield.

### BRIEF DESCRIPTION OF THE DRAWINGS

Aspects of this disclosure are best understood from the following detailed description when read with the accompanying figures.

FIG. 1A illustrates a top-down view of a passive device die with measurement structures, in accordance with some embodiments.

FIGS. 1B and 1C illustrate cross-sectional views of different regions of a passive device die with measurement structures, in accordance with some embodiments.

FIG. 1D illustrates a cross-sectional view of measurement structures in a passive device die, in accordance with some embodiments.

FIGS. 1E and 1F illustrate cross-sectional views of different regions of a passive device coupled to an interconnect structure in a passive device die with measurement structures, in accordance with some embodiments.

FIG. 2A illustrates a top-down view of another passive device die with measurement structures, in accordance with some embodiments.

FIG. 2B illustrates a cross-sectional view of measurement structures in another passive device die, in accordance with some embodiments.

FIG. 3 is a flow diagram of a method for fabricating a passive device die with measurement structures, in accordance with some embodiments.

FIGS. 4-9 illustrate cross-sectional views of a passive device die with measurement structures at various stages of its fabrication process, in accordance with some embodiments.

Illustrative embodiments will now be described with reference to the accompanying drawings. In the drawings, like reference numerals generally indicate identical, functionally similar, and/or structurally similar elements. The discussion of elements with the same annotations applies to each other, unless mentioned otherwise.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the process for forming a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Spatially relative terms, such as “beneath,” “below,” “lower,” “above,” “upper,” and the like may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 5% of the value (e.g., ±1%, ±2%, ±3%, ±4%, ±5% of the value). These values are merely examples and are not intended to be limiting. The terms “about” and “substantially” can refer to a percentage of the values as interpreted by those skilled in relevant art(s) in light of the teachings herein.

The present disclosure provides example structures and methods for improving the manufacturing yield of wafers having passive device dies, such as trench capacitor dies. In some embodiments, a trench capacitor die can be referred to a die disposed on a wafer (also referred to as a “substrate”) that includes trench capacitors and does not include other passive or active devices. In some embodiments, each trench capacitor can include two or more capacitors stacked over one another in a metal-insulator-metal (MIM) configuration and electrically connected to each other in a parallel configuration. In some embodiments, portions of the two or more capacitors are disposed in trenches in the substrate for which the capacitors can be referred to as “trench capacitors” or “deep trench capacitors (DTCs).”

In some embodiments, each trench capacitor can include a stack of first, second, third, and fourth conductive layers disposed in one or more trenches in the substrate. The stack can further include a first high-k dielectric layer disposed between the first and second conductive layers, a second first high-k dielectric layer disposed between the second and third conductive layers, a third high-k dielectric layer disposed between the third and fourth conductive layers, and a fourth high-k dielectric layer disposed on the fourth conductive layer. In some embodiments, each trench capacitor can further include first, second, third, and fourth contact structures (e.g., vias) disposed on the first, second, third, and fourth conductive layers, respectively.

A first capacitor can be formed between the first and second conductive layers, a second capacitor can be formed between the second and third conductive layers, and a third capacitor can be formed between the third and fourth conductive layers. The first, second, and third capacitors can be electrically connected in parallel to each other. In some embodiments, the first and third contact structures can electrically connect the first and third conductive layers to a first voltage (e.g., a ground reference voltage, Vss). The second and fourth contact structures can electrically connect the second and fourth conductive layers to a second voltage (e.g., a power supply voltage, Vdd) that is higher than the first voltage.

In some embodiments, each trench capacitor die can further include an interconnect structure disposed on the trench capacitors, bonding structures disposed on the interconnect structure, and measurement structures disposed on the interconnect structure. The interconnect structure can be configured to provide an electrical connection between the trench capacitors and the measurement structures and between the trench capacitors and the bonding structures. The measurement structures can include conductive pads and can be configured to detect and identify the defective trench capacitors in the trench capacitor die. The bonding structures can include conductive pads and solder bumps and can be configured to electrically connect the non-defective trench capacitors to other peripheral circuits and/or integrated circuit dies. A defective trench capacitor can refer to a malfunctioning trench capacitor.

In some embodiments, the trench capacitors in each trench capacitor die can be divided into groups of trench capacitors. In some embodiments, one or more of the groups of trench capacitors are formed in addition to the number of groups of trench capacitors desired for each trench capacitor die. These additional groups of trench capacitors are formed as reserve groups of trench capacitors, which can be used to replace one or more groups of trench capacitors that are found to be defective after the fabrication of the trench capacitor dies.

In some embodiments, each group of trench capacitors can be electrically connected to (i) a pair of metal lines in the topmost metal line layer of the interconnect structure, (ii) a pair of bonding structures, and (iii) a pair of measurement structures. The first metal line of each pair of metal lines can be electrically connected to the first voltage and to the corresponding group of trench capacitors through the first and third contact structures. The second metal line of each pair of metal lines can be electrically connected to the second voltage and to the corresponding group of trench capacitors through the second and fourth contact structures. In some embodiments, the first and second bonding structures of each pair of bonding structures can be electrically connected to the first and second metal lines of each respective pair of metal lines. In some embodiments, the first and second measurement structures of each pair of measurement structures can be electrically connected to the first and second metal lines of each respective pair of metal lines.

With such configurations of the metal lines and measurement structures, the electrical properties (e.g., capacitance) of each group of trench capacitors can be extracted through the measurement structures with a test system including a probe card and a measurement apparatus. Based on the extracted electrical properties, the presence and absence of defective group(s) of trench capacitors in the manufactured trench capacitor dies can be detected and identified. For example, the capacitance measured from the measurement structures can indicate the presence of defective trench capacitors if the capacitance is below or different from a value expected from the trench capacitors. On the other hand, the capacitance measured from the measurement structures can indicate the absence of defective trench capacitors if the capacitance is equal to the value expected from the trench capacitors. In response to the detection of defective group(s) of trench capacitors, the electrical connections between the bonding structures and the defective group(s) of trench capacitors can be reconfigured to electrically disconnect the defective group(s) of trench capacitors from the bonding structures. On the other hand, in response to the absence of defective group(s) of trench capacitors, the electrical connections between the bonding structures and the reserve group(s) of trench capacitors can be reconfigured to electrically disconnect the reserve group(s) of trench capacitors from the bonding structures. As a result, trench capacitor dies with the desired number of non-defective groups of trench capacitors can be achieved and the wafer manufacturing yield can be improved.

In some embodiments, the reconfiguration of the electrical connections between the bonding structures and the defective group(s) of trench capacitors can include cutting the first and second metal lines of the corresponding defective group(s) of trench capacitors. Similarly, the reconfiguration of the electrical connections between the bonding structures and the reserve group(s) of trench capacitors can include cutting the first and second metal lines of the corresponding reserve group(s) of trench capacitors. In some embodiments, the cutting can include removing portions of the first and second metal lines using a laser cutting tool. In some embodiments, the reconfiguration process can be performed on the trench capacitor dies prior to performing a die singulation process on the wafer to separate the trench capacitor dies from each other for individually packaging the singulated trench capacitor dies. In some embodiments, the reconfiguration process can be performed on the trench capacitor dies after performing the die singulation process, but prior to individually packaging the singulated trench capacitor dies.

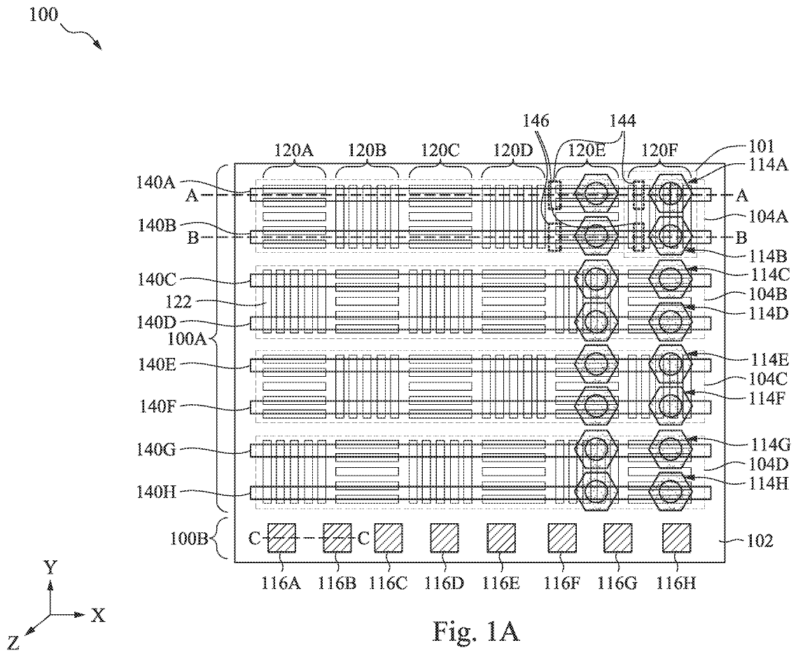

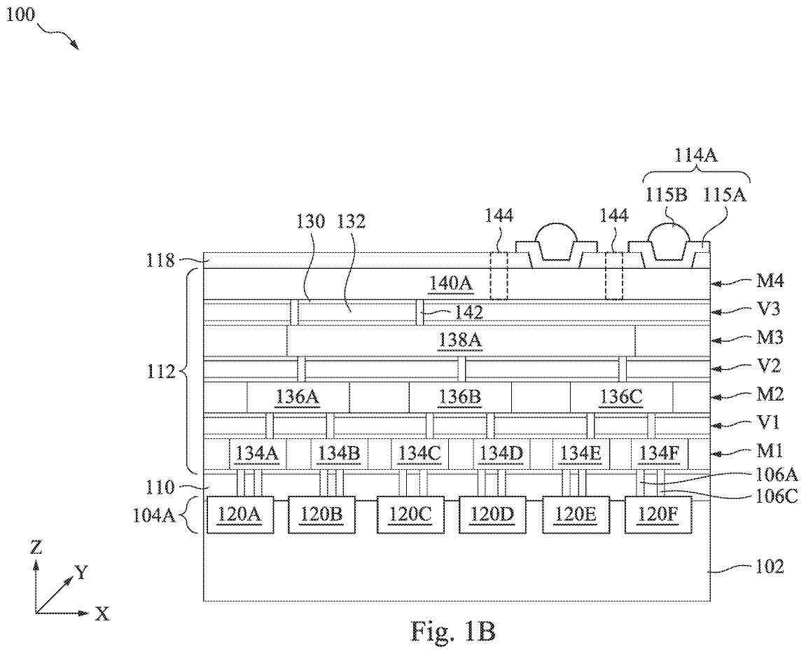

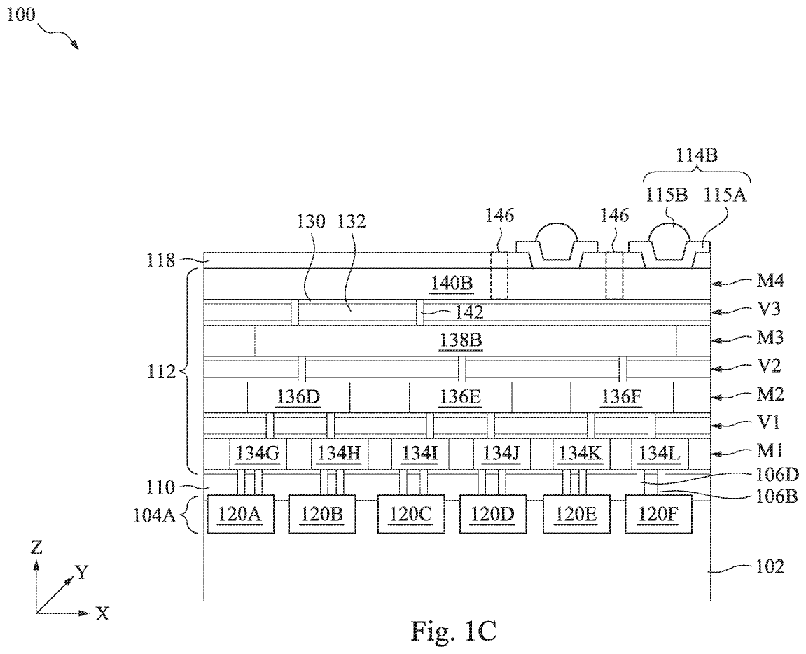

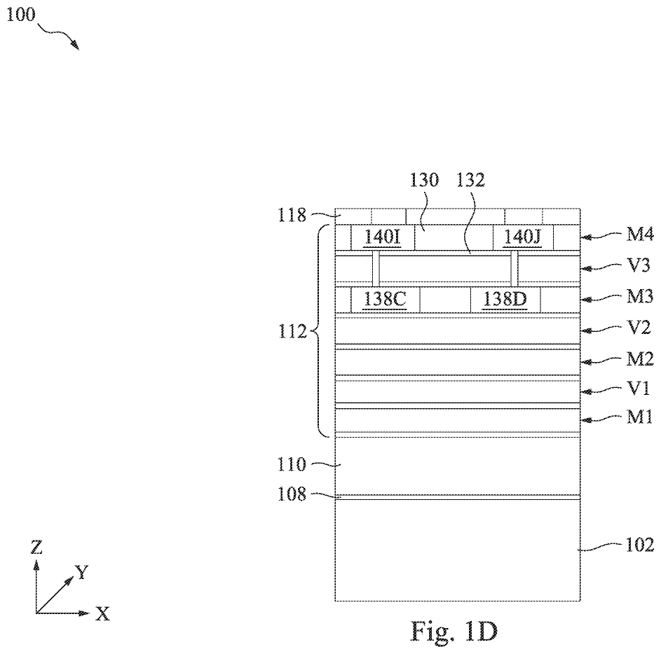

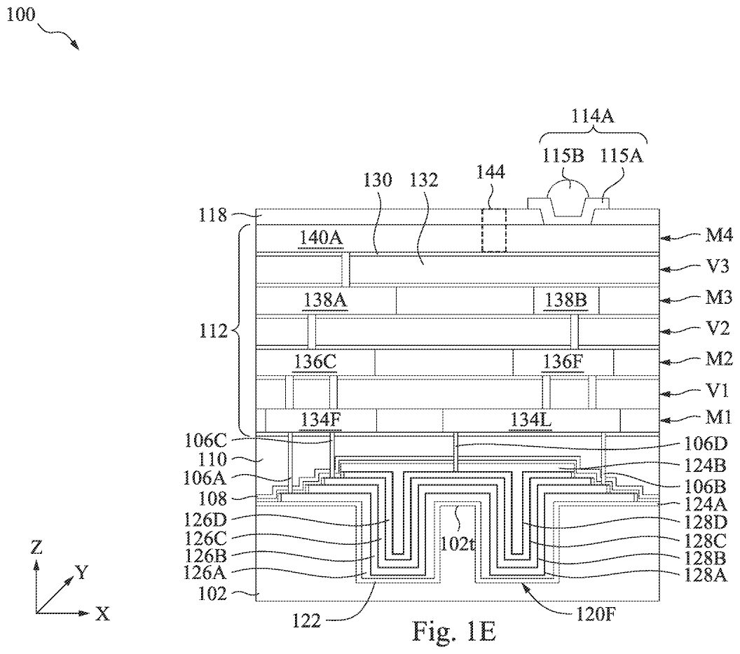

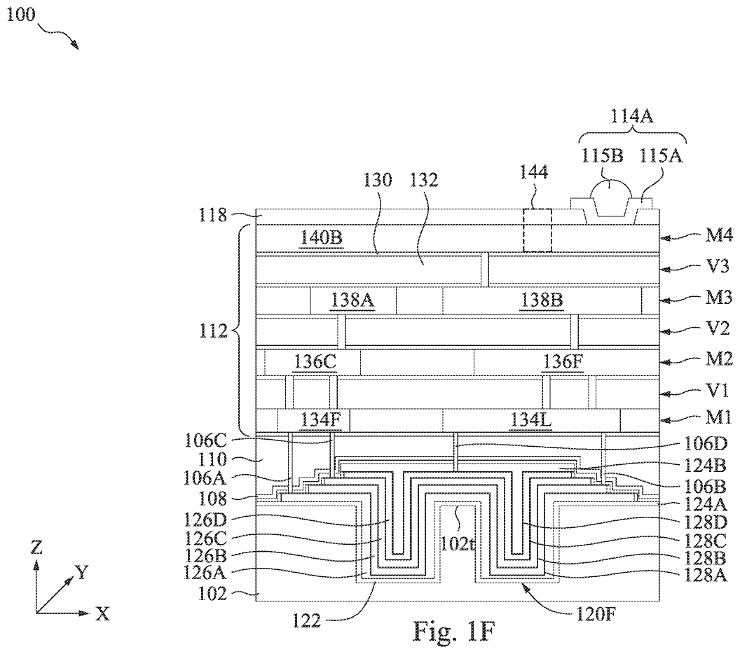

A passive device die 100 (also referred to as “trench capacitor die 100”) is described with reference to FIGS. 1A, 1B, 1C, 1D, 1E, and 1F. FIG. 1A illustrates a top-down view of passive device die 100, according to some embodiments. FIG. 1B illustrates a cross-sectional view of passive device die 100 along line A-A of FIG. 1A, according to some embodiments. FIG. 1C illustrates a cross-sectional view of passive device die 100 along line B-B of FIG. 1A, according to some embodiments. FIG. 1D illustrates a cross-sectional view of passive device die 100 along line C-C of FIG. 1A, according to some embodiments. FIG. 1E illustrates another cross-sectional view of passive device die 100 along line A-A in region 101 of FIG. 1A, according to some embodiments. FIG. 1F illustrates another cross-sectional view of passive device die 100 along line B-B in region 101 of FIG. 1A, according to some embodiments. FIGS. 1B, 1C, 1D, 1E and 1F illustrate views of passive device die 100 with additional structures that are not shown in FIG. 1A for simplicity. FIGS. 1E and 1F illustrate views of passive device die 100 with additional structures that are not shown in FIGS. 1A, 1B, and 1C for simplicity. The discussion of elements in FIGS. 1A, 1B, 1C, 1D, 1E, and 1F with the same annotations applies to each other, unless mentioned otherwise.

Referring to FIGS. 1A-1F, in some embodiments, passive device die 100 can include (i) a substrate 102, (ii) trench capacitor groups 104A-104D (also referred to as “passive device groups 104A-104D”) disposed on substrate 102, (iii) contact structures 106A, 106B, 106C, and 106D disposed on trench capacitor groups 104A-104D, (iv) an etch stop layer (ESL) 108 disposed on trench capacitor groups 104A-104D, (v) an interlayer dielectric (ILD) layer 110 disposed on ESL 108, (vi) an interconnect structure 112 disposed on trench capacitor groups 104A-104D, (vii) bonding structures 114A-114H disposed on interconnect structure 112, (viii) measurement structures 116A-116H disposed on interconnect structure 112, and (ix) a passivation layer 118 disposed on interconnect structure 112. In some embodiments, passive device die 100 can be divided into a device region 100A including trench capacitor groups 104A, 104B, 104C, and 104D and a measurement region 100B including measurement structures 116A-116H. In some embodiments, device region 100A may not include any measurement structures and measurement region 100B may not include any devices, such as trench capacitors.

In some embodiments, substrate 102 can include a semiconductor material, such as silicon, germanium (Ge), silicon germanium (SiGe), a silicon-on-insulator (SOI) structure, and a combination thereof. In some embodiments, substrate 102 can be doped with p-type dopants (e.g., boron, indium, aluminum, or gallium) or n-type dopants (e.g., phosphorus or arsenic).

In some embodiments, trench capacitor groups 104A-104C can be the desired number of trench capacitor groups for passive device die 100 and trench capacitor group 104D can be the reserve trench capacitor group for use if a trench capacitor group 104A, 104B, or 104C is found to be defective. The method of detecting defects in trench capacitor groups 104A and 104B and the use of trench capacitor groups 104C and 104D are discussed in detail below. In some embodiments, each of trench capacitor groups 104A, 104B, 104C, and 104D can include trench capacitors 120A-120F (also referred to as “passive devices 120A-120F”). The number of trench capacitor groups and trench capacitors shown in FIGS. 1A, 1B, and 1C are exemplary and not limiting. In some embodiments, passive device die 100 can have two or more trench capacitor groups and each trench capacitor can have any number of trench capacitors. The number of trench capacitors in each trench capacitor group can be equal to each other.

An example structure of trench capacitors 120A-120F is described with reference to the top-down and cross-sectional views of trench capacitor 120F in FIGS. 1A, 1E and 1F. The structural elements of trench capacitors 120A-120F are not shown in FIGS. 1B and 1C for simplicity. The discussion of trench capacitor 120F applies to trench capacitors 120A-120E, unless mentioned otherwise. In some embodiments, trench capacitor 120F can include trenches 122. The number of trenches 122 shown in FIG. 1A is exemplary and not limiting. FIGS. 1E and 1F show two of the five trenches 122 shown in FIG. 1A for simplicity. In some embodiments, trenches 122 of adjacent trench capacitors are substantially perpendicular to each other, as shown in FIG. 1A. Such directional arrangement of trenches 122 can reduce stress on substrate 102 during the formation of trenches 122 to protect the structural integrity of substrate 102.

Referring to FIGS. 1E and 1F, in some embodiments, trench capacitor 120F can further include (i) dielectric oxide layers 124A and 124B, (ii) a conductive layer 126A disposed directly on dielectric oxide layer 124A, (iii) a high-k dielectric layer 128A disposed directly on conductive layer 126A, (iii) a conductive layer 126B disposed directly on high-k dielectric layer 128A, (iv) a high-k dielectric layer 128B disposed directly on conductive layer 126B, (v) a conductive layer 126C disposed directly on high-k dielectric layer 128B, (vi) a high-k dielectric layer 128C disposed directly on conductive layer 126C, (vii) a conductive layer 126D disposed directly on high-k dielectric layer 128C, and (viii) a high-k dielectric layer 128D disposed directly on conductive layer 126D. These elements of trench capacitor 120F are not shown in FIG. 1A for simplicity.

In some embodiments, high-k dielectric layer 128D may be absent. In some embodiments, conductive layers 126A, 126B, 126C, and 126D can include a conductive material, such as titanium nitride (TiN), aluminum (Al), copper (Cu), and other suitable conductive materials. In some embodiments, high-k dielectric layer 128A, 128B, 128C, and 128D can include a high-k dielectric material, such as hafnium oxide (HfO₂), titanium oxide (TiO₂), hafnium zirconium oxide (HfZrO), tantalum oxide (Ta₂O₃), hafnium silicate (HfSiO₄), zirconium oxide (ZrO₂), zirconium silicate (ZrSiO₂), aluminum oxide (Al₂O₃), and other suitable high-k dielectric materials. Each of conductive layers 126A, 126B, 126C, and 126D can be disposed partly in trenches 122 and partly on top surface 102t of substrate 102, as shown in FIGS. 1E and 1F. Each of conductive layers 126A, 126B, 126C, and 126D can form a U-shaped layer in trenches 122. In some embodiments, conductive layers 126A, 126B, 126C, and 126D overlap with each other, except (i) the end portions of conductive layer 126A on top surface 102t of substrate 102 are non-overlapping with conductive layers 126B, 126C, and 126D, (ii) the end portions of conductive layer 126B on conductive layer 126A are non-overlapping with conductive layers 126C and 126D, and (iii) the end portions of conductive layer 126C on conductive layer 126B are non-overlapping with conductive layer 126D.

Dielectric oxide layer 124A can be disposed partly in trenches 122 and partly on top surface 102t of substrate 102. Dielectric oxide layer 124B can be disposed directly on conductive layer 126D and in trenches 122. In some embodiments, dielectric oxide layers 124A and 124B can include silicon oxide (SiO₂), undoped silicate glass, or other suitable dielectric oxide materials. In some embodiments, ESL 108 and ILD layer 110 can include an insulating material, such as SiO₂, silicon nitride (SiN), silicon oxynitride (SiON), silicon oxycarbon nitride (SiOCN), and silicon carbide (SiC).

In some embodiments, conductive layers 126A, 126B, 126C, and 126D can be electrically coupled to power sources (not shown) through contact structures 106A, 106C, 106B, and 106D, respectively, as described below. In some embodiments, contact structures 106A, 106C, 106B, and 106D can include a conductive material, such as Al, Cu, tungsten (W), and other suitable conductive materials. In some embodiments, one or more contact structures 106A can be disposed directly on the end portions of conductive layer 126A through ESL 108 and ILD layer 110 (shown in FIGS. 1E and 1F). In some embodiments, one or more contact structures 106B can be disposed directly on the end portions of conductive layer 126B through ESL 108 and ILD layer 110 (shown in FIGS. 1E and 1F). In some embodiments, one or more contact structures 106C can be disposed directly on the end portions of conductive layer 126C through ESL 108 and ILD layer 110 (shown in FIGS. 1E and 1F). In some embodiments, one or more contact structures 106D can be disposed directly on conductive layer 126D through ESL 108, ILD layer 110, and dielectric oxide layer 124B (shown in FIGS. 1E and 1F).

In some embodiments, more than one of each contact structures 106A, 106C, 106B, and 106D can be disposed on conductive layers 126A, 126B, 126C, and 126D, respectively. Increasing the number of contact structures 106A, 106C, 106B, and 106D can increase the contact area between contact structures 106A, 106C, 106B, and 106D and conductive layers 126A, 126B, 126C, and 126D, thus improving the electrical connection of trench capacitor 120F and interconnect structure 112. In some embodiments, contact structures 106A and 106C can be electrically connected to a first power source (e.g., a FET or a power supply; not shown) through interconnect structure 112 to provide a first voltage V1 to conductive layers 126A and 126C. Also, contact structures 106B and 106D can be electrically connected to a second power source (not shown) through interconnect structure 112 to provide a second voltage V2 to conductive layers 126B and 126D that is higher or lower than first voltage V1. In some embodiments, first voltage V1 can be a power supply voltage, Vdd and second voltage V2 can be a ground reference voltage, Vss. Thus, the odd-numbered conductive layers, such as conductive layers 126A and 126C of trench capacitor 120F, can be electrically connected to the same voltage level (e.g., first voltage V1) and the even-numbered conductive layers, such as conductive layers 126B and 126D of trench capacitor 120F, can be electrically connected to the same voltage level (e.g., second voltage V2). And, the odd-numbered conductive layers and the even-numbered conductive layers can be electrically connected to different voltage levels.

In some embodiments, such electrical configuration between conductive layers 126A, 126B, 126C, and 126D can form capacitors C1, C2, and C3. Conductive layers 126A and 126B can form the parallel plates of capacitor C1, which are separated by high-k dielectric layer 128A. Conductive layers 126B and 126C can form the parallel plates of capacitor C2, which are separated by high-k dielectric layer 128B. Conductive layers 126C and 126D can form the parallel plates of capacitor C3, which are separated by high-k dielectric layer 128C. Capacitor C1 and capacitor C2 share conductive layer 126B as a common plate and capacitor C2 and capacitor C3 share conductive layer 126C as a common plate. Thus, trench capacitor 120F can have capacitors C1, C2, and C3 disposed in a stacked configuration in trenches 122 and connected in parallel to each other. Though trench capacitor 120F is shown to have three capacitors C1, C2, and C3, trench capacitor 120F can have any number of capacitors formed in trenches 122 in a stacked configuration and connected in parallel to each other.

Referring to FIGS. 1A-1F, in some embodiments, interconnect structure 112 can include metal line layers M1, M2, M3, and M4 and via layers V1, V2, and V3. Via layer V1 provides an electrical connection between metal line layers M1 and M2, via layer V2 provides an electrical connection between metal line layers M2 and M3, and via layer V3 provides an electrical connection between metal line layers M3 and M4. The number of metal line layers and via layers are exemplary and not limiting. In some embodiments, interconnect structure 112 can further include ESLs 130 and ILD layers 132. In some embodiments, ESLs 130 can include a dielectric material, such as aluminum oxide (AlxOA nitrogen doped silicon carbide (SiCN), and oxygen doped silicon carbide (SiCO) with a dielectric constant ranging from about 4 to about 10. In some embodiments, ILD layers 132 can include a low-k (LK) or extra low-k (ELK) dielectric material with a dielectric constant lower than that of silicon oxide (e.g., dielectric constant between about 2 and about 3.7). In some embodiments, the LK or ELK dielectric material can include silicon oxycarbide (SiOC), nitrogen doped silicon carbide (SiCN), SiCON, or oxygen doped silicon carbide.

In some embodiments, metal line layer M1 can include metal lines 134A-134L, metal line layer M2 can include metal lines 136A-136F, metal line layer M3 can include metal lines 138A-138D, metal line layer M4 can include metal lines 140A-140J, and via layers V1-V3 can include metal vias 142. In some embodiments, metal lines 134A-134L, 136A-136F, 138A-138D, and 140A-140J, and metal vias 142 can include an electrically conductive material, such as Cu, ruthenium (Ru), cobalt (Co), molybdenum (Mo), a Cu alloy (e.g., Cu—Ru, Cu—Al, or copper-manganese (CuMn)), and other suitable conductive materials. As metal line layer M4 is the top most layer of interconnect structure 112, metal line layer M4 can be referred to as the “top metal line layer” and metal lines 140A-140J can be referred to as the “top metal lines.”

In some embodiments, each trench capacitors 120A-102F of each trench capacitor groups 104A-104D can be electrically connected to the first and second voltages V1 and V2 through a pair of top metal lines. For example, trench capacitors 120A-102F of trench capacitor group 104A can be electrically connected to the first voltage V1 through metal line 140A and to the second voltage V2 through metal line 140B, trench capacitors 120A-102F of trench capacitor group 104B can be electrically connected to the first voltage V1 through metal line 140C and to the second voltage V2 through metal line 140D, trench capacitors 120A-102F of trench capacitor group 104C can be electrically connected to the first voltage V1 through metal line 140E and to the second voltage V2 through metal line 140F, and trench capacitors 120A-102F of trench capacitor group 104D can be electrically connected to the first voltage V1 through metal line 140G and to the second voltage V2 through metal line 140H. By connecting each of trench capacitor groups 104A-104D to the first and second voltages V1 and V2 through individual pairs of top metal lines, a defective trench capacitor group can be individually disconnected without disconnecting the non-defective trench capacitor groups, as discussed in detail below. A defective trench capacitor group can refer to a trench capacitor group that has one or more malfunctioning trench capacitors.

In some embodiments, each of trench capacitors 120A-120F may not be electrically connected to the pair of top metal lines directly and individually for the ease of fabrication and/or for the efficient use of device space on substrate 102. In some embodiments, trench capacitors 120A-120F of trench capacitor group 104A can be electrically connected to the pair of top metal lines 140A and 140B through layout configurations of metal lines and vias as illustrated in FIGS. 1B and 1C. FIG. 1B illustrates an example layout configuration of metal lines and vias that can electrically connect trench capacitors 120A-120F to top metal line 140A. Similarly, FIG. 1C illustrates an example layout configuration of metal lines and vias that can electrically connect trench capacitors 120A-120F to top metal line 140B. Referring to FIG. 1B, trench capacitors 120A-120F can be electrically connected to individual metal lines 134A-134F, respectively, of metal line layer M1. Pairs of metal lines—134A-134B, 134C-134D, and 134E-134F—of metal line layer M1 can be electrically connected to common metal lines 136A, 136B, and 136C of metal line layer M2, which can be electrically connected to a common metal line 138A of metal line layer M3. And, metal line 138A can be electrically connected to top metal line 140A. Similarly, referring to FIG. 1C, trench capacitors 120A-120F can be electrically connected to individual metal lines 134G-134L, respectively, of metal line layer M1. Pairs of metal lines—134G-134H, 134I-134J, and 134K-134L—of metal line layer M1 can be electrically connected to common metal lines 136D, 136E, and 136F of metal line layer M2, which can be electrically connected to a common metal line 138B of metal line layer M3. And, metal line 138B can be electrically connected to top metal line 140B. In some embodiments, trench capacitors 120A-120F of other trench capacitor groups 104B, 104C, and 104D can be electrically connected to corresponding top metal lines 140C-140H in a layout configuration similar to or different from that illustrated in FIGS. 1B and 1C.

Referring to FIGS. 1A, 1B, 1C, 1E, and 1F, bonding structures 114A-114H can be disposed directly on top metal lines 140A-140H, respectively. Each of bonding structures 114A-114H can include metal pads 115A disposed directly on top metal lines 140A-140H and solder bumps 115B disposed directly on metal pads 115A. Bonding structures 114A-114H can be electrically isolated from each other by passivation layer 118 disposed on interconnect structure 112. Furthermore, bonding structures 114A-114H can be configured to electrically connect trench capacitors 120A-120F of trench capacitor groups 104A-104D to peripheral circuits and/or integrated circuit dies. Each of trench capacitor groups 104A-104D can be electrically connected to at least a pair of bonding structures through top metal lines. For example, trench capacitor group 104A can be electrically connected to bonding structures 114A and 114B through top metal lines 140A and 140B, respectively, trench capacitor group 104B can be electrically connected to bonding structures 114C and 114D through top metal lines 140C and 140D, respectively, trench capacitor group 104C can be electrically connected to bonding structures 114E and 114F through top metal lines 140E and 140F, respectively, and trench capacitor group 104D can be electrically connected to bonding structures 114G and 114H through top metal lines 140G and 140H, respectively.

By connecting trench capacitor groups to individual pairs of bonding structures through individual pairs of top metal lines, the electrical connections between a defective trench capacitor group and the corresponding bonding structures can be disconnected without disconnecting the electrical connections between the non-defective trench capacitor groups and the corresponding bonding structures. For example, if trench capacitor group 104A is defective, the electrical connection between trench capacitor group 104A and bonding structures 114A can be disconnected by cutting regions 144 of top metal line 140A. And, the electrical connection between trench capacitor group 104A and bonding structures 114B can be disconnected by cutting regions 146 of top metal line 140B. Regions 144 and 146 can referred to as “metal cut regions.” Cutting regions 144 and 146 can include removing the conductive material of top metal lines 140A and 140B from regions 144 and 146 and forming trenches in regions 144 and 146. In some embodiments, the trenches can be filled with an insulating material. Thus, by disconnecting trench capacitor group 104A from bonding structures 114A and 114B, the malfunctioning part of passive device die 100 can be selectively isolated from the non-defective parts (e.g., trench capacitor groups 104B-104D) of passive device die 100, which prevents the entire passive device die 100 from failing. As a result, the manufacturing yield of passive device die 100 can be improved.

The manufacturing yield of passive device die 100 can be further improved with the use of one or more reserve trench capacitor group. The reserve trench capacitor groups can include trench capacitors formed in addition to the number of trench capacitors desired for a passive device die. Each reserve trench capacitor group can be used to replace the function of each defective trench capacitor group, thus keeping the number of functioning trench capacitors equal to the desired number. For example, trench capacitor groups 104A-104C can have the desired number of trench capacitors for passive device die 100 and trench capacitor group 104D can form the reserve trench capacitor groups. If trench capacitor group 104A is defective and top metal lines 140A and 140B are disconnected at metal cut regions 144 and 146, reserve trench capacitor group 104D can be used to replace the function of trench capacitor group 104A. On the other hand, if none of trench capacitor groups 104A-104C are defective, reserve trench capacitor group 104D can be disconnected from bonding structures 114G and 114H by cutting top metal lines 140G and 140H in regions similar to metal cut regions 144 and 146. Thus, with the use of reserve trench capacitor group, the total number of desired trench capacitor groups for passive device die 100 can be maintained and manufacturing yield loss can be prevented.

In some embodiments, the presence and absence of defective trench capacitor groups in passive device die 100 can be detected with the use of measurement structures 116A-116H. For example, measurement structures 116A-116B can be configured to determine if trench capacitor group 104A is defective, measurement structures 116C-116D can be configured to determine if trench capacitor group 104A is defective, measurement structures 116E-116F can be configured to determine if trench capacitor group 104C is defective, and measurement structures 116G-116H can be configured to determine if trench capacitor group 104D is defective. Thus, the total number of measurement structures in passive device die 100 can be equal to twice the number of trench capacitor groups. In some embodiments, measurement structure 116A can be electrically connected to top metal line 140A through metal lines 1401 and 138C and measurement structure 116B can be electrically connected to top metal line 140B through metal lines 1401 and 138D, as shown in FIG. 1D. Similarly, measurement structures 116C-116H can be electrically connected to top metal lines 140C-140H, respectively, through other metal lines of metal line layers M4 and M3. In some embodiments, each of measurement structures 116A-116H can include a conductive material, such as Cu, Al, W, and Ru. Measurement structures 116A-116H can be electrically isolated from each other by passivation layer 118.

The electrical properties of trench capacitor groups 104A-10D can be extracted through measurement structures 116A-116H with a test system including a probe card and a measurement apparatus. The probe card can contact each pair of measurement structures 116A-116B, 116C-116D, 116E-116F, and 116G-116H to measure the electrical properties of trench capacitor groups 104A, 104B, 104C, and 104D. Based on the measured electrical properties, the presence and absence of defective trench capacitor groups in passive device die 100 can be detected and identified. In response to the detection of a defective trench capacitor group, the electrical connections between the bonding structures and the defective trench capacitor group can be reconfigured to electrically disconnect the defective trench capacitor groups from the bonding structures, as discussed above. On the other hand, in response to the absence of defective trench capacitor groups, the electrical connections between the bonding structures and the reserve trench capacitor groups can be reconfigured to electrically disconnect the reserve trench capacitor groups from the bonding structures, as discussed above.

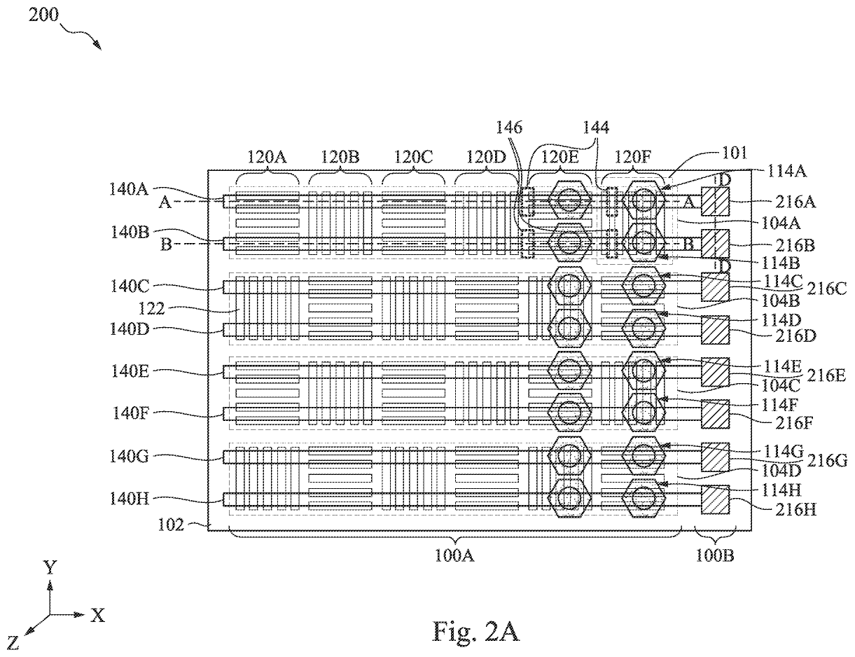

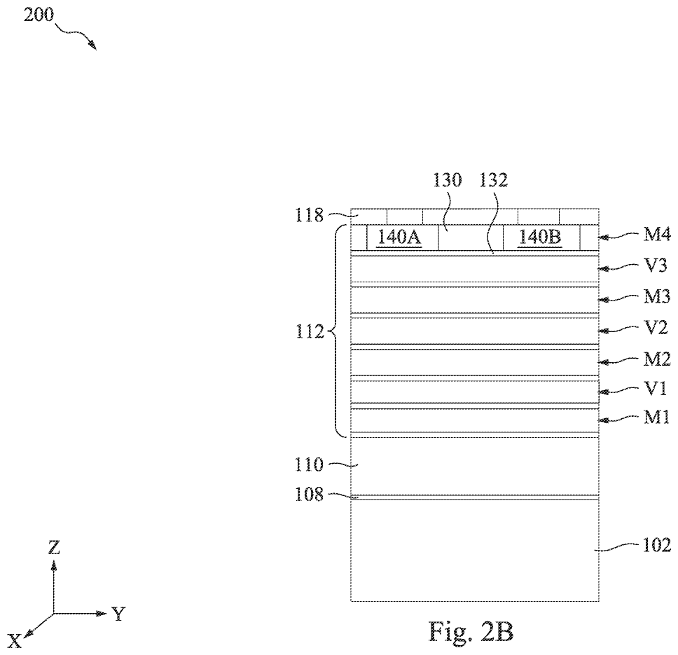

FIG. 2A illustrates a top-down view of passive device die 200, according to some embodiments. FIG. 2B illustrates a cross-sectional view of passive device die 200 along line D-D of FIG. 2A, according to some embodiments. The discussion of elements in FIGS. 1A-1F and 2A-2B with the same annotations applies to each other, unless mentioned otherwise.

The discussion of passive device die 100 applies to passive device die 200, unless mentioned otherwise. In some embodiments, passive device die 200 can include measurement structures 216A-216H, instead of measurement structures 116A-116H of passive device die 100. The discussion of measurement structures 116A-116H applies to measurement structures 216A-216H, unless mentioned otherwise. Unlike measurement structures 116A-116H, measurement structures 216A-216H can be directed connected to and directly disposed on top metal lines 140A-140H, respectively.

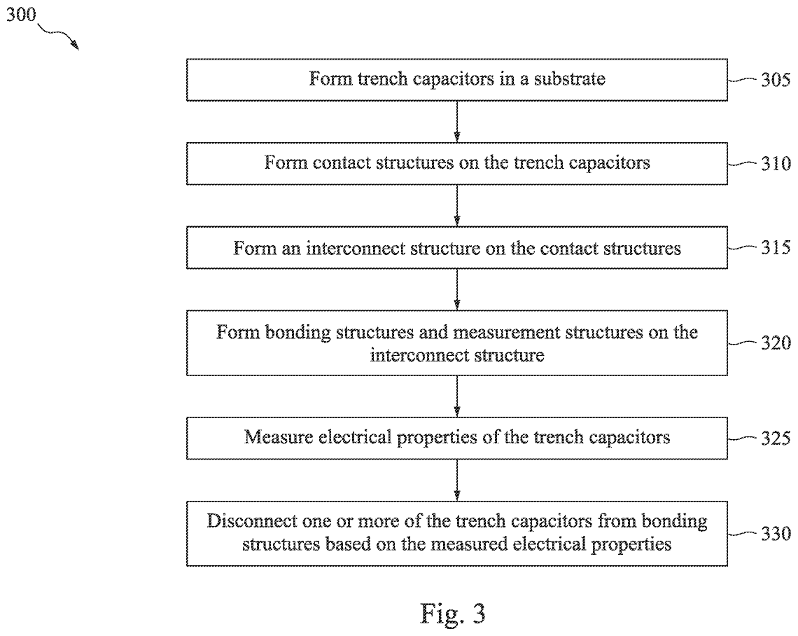

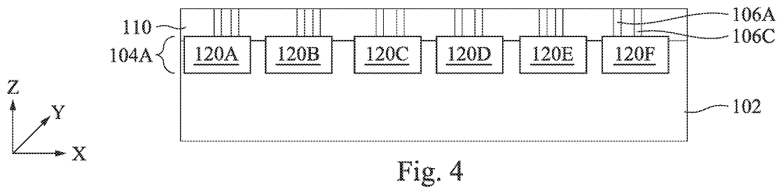

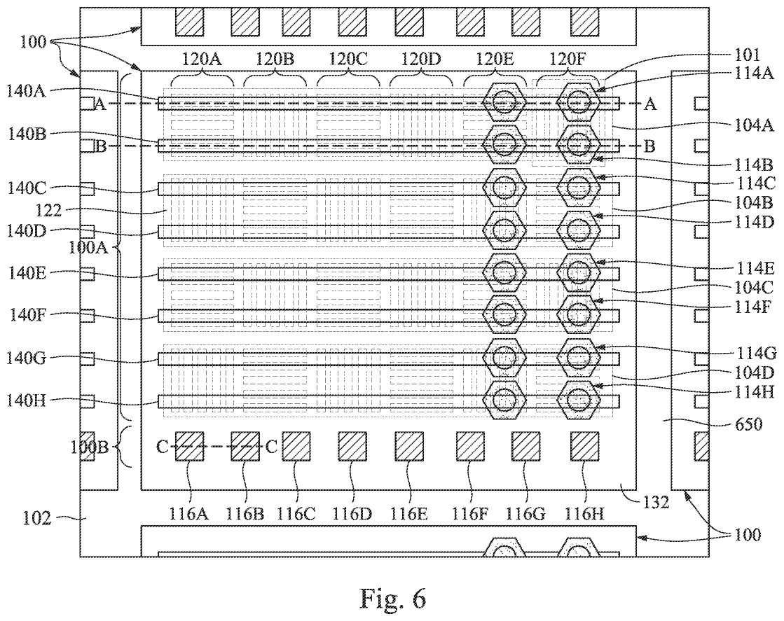

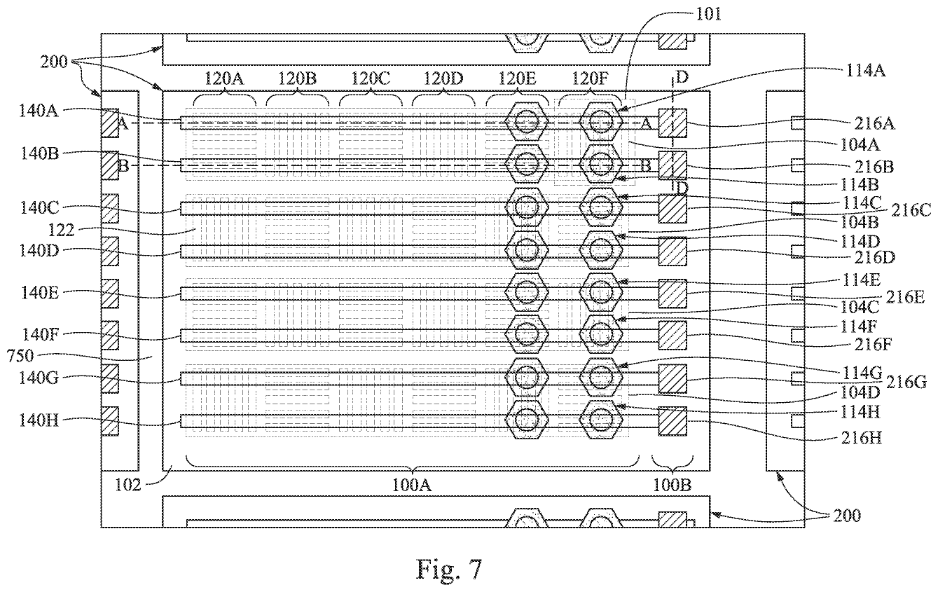

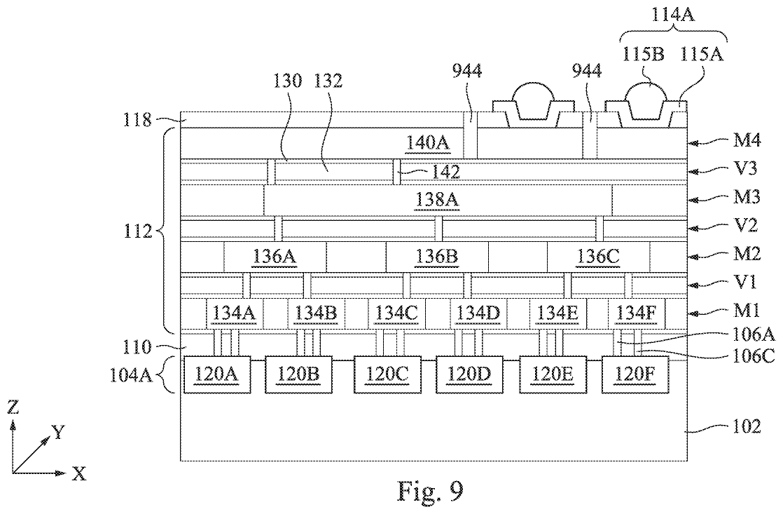

FIG. 3 is a flow diagram of an example method 300 for fabricating passive device dies 100 and 200, according to some embodiments. For illustrative purposes, the operations illustrated in FIG. 3 will be described with reference to the example fabrication process for fabricating passive device dies 100 and 200 as illustrated in FIGS. 4-9. FIGS. 4-5 and 8-9 are cross-sectional views of passive device dies 100 and 200 along line A-A of FIGS. 1A and 2A at various stages of their fabrication, according to some embodiments. FIGS. 6 and 7 are top-down views of passive device dies 100 and 200, respectively, at a stage of their fabrication, according to some embodiments. Operations can be performed in a different order or not performed depending on specific applications. It should be noted that method 300 may not produce complete passive device dies 100 and 200. Accordingly, it is understood that additional processes can be provided before, during, and after method 300, and that some other processes may only be briefly described herein. Elements in FIGS. 4-9 with the same annotations as elements in FIGS. 1A-1F and 2A-2B are described above.

Referring to FIG. 4, in operation 305, trench capacitors are formed in substrate 102. For example, as shown in FIG. 4, trench capacitors 120A-120F of trench capacitor group 104A are formed in substrate 102. Trench capacitors 120A-120F of trench capacitor groups 104B-104D (not visible in cross-sectional view of FIG. 4) are formed at the same time as trench capacitors 120A-120F of trench capacitor group 104A. The formation of trench capacitors 120A-120F can be followed by the formation of ILD layer 110.

Referring to FIG. 4, in operation 310, contact structures are formed on the trench capacitors. For example, as shown in FIG. 4, contact structures 106A and 106C are formed on trench capacitors 120A-120F. Contact structures 106B and 106D (not visible in cross-sectional view of FIG. 4) are also formed on trench capacitors 120A-120F along with contact structures 106A and 106C.

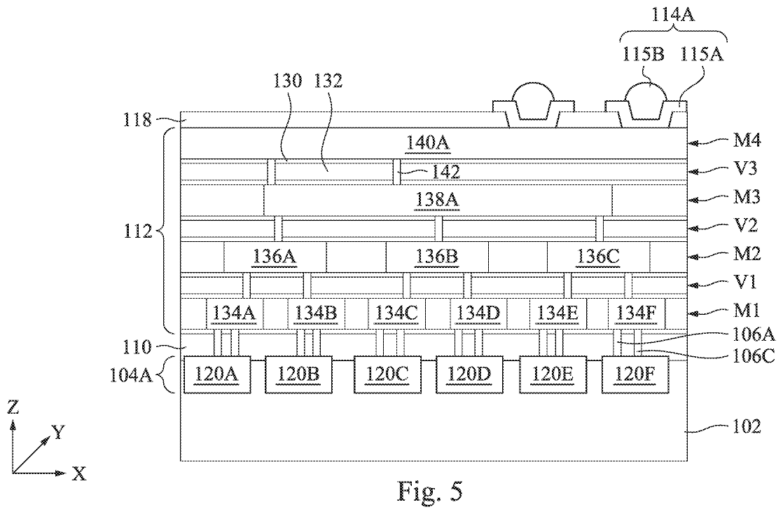

Referring to FIG. 4, in operation 315, an interconnect structure is formed on the contact structures. For example, as shown in FIG. 5, interconnect structure 112 is formed on contact structures 106A and 106C and contact structures 106B and 106D (not visible in cross-sectional view of FIG. 5). The formation of interconnect structure 112 can be followed by the deposition of passivation layer 118 on interconnect structure 112.

Referring to FIG. 4, in operation 320, bonding structures and measurement structures are formed on the interconnect structure. For example, as shown in FIG. 5, bonding structures 114A can be formed on top metal line 140A through passivation layer 118. Bonding structures 114B-114H (not visible in cross-sectional view of FIG. 5) can also formed on top metal lines 140B-140H, respectively, at the same time as bonding structures 114A. In some embodiments, measurement structures 116A-116H or 216A-216H (not visible in cross-sectional view of FIG. 5, shown in FIGS. 1D and 2B) can be formed on interconnect structure 112 before or after the formation of bonding structures 114A-114H.

In some embodiments, operations 305-320 can be performed on substrate 102 to form a plurality of passive device dies 100, as shown in FIG. 6, or a plurality of passive device dies 200, as shown in FIG. 7. Passive device dies 100 can be separated from each other by scribe lane areas 650, as shown in FIG. 6, and passive device dies 200 can be separated from each other by scribe lane areas 750, as shown in FIG. 7.

Referring to FIG. 4, in operation 325, electrical properties of the trench capacitors are measured. For example, referring to FIG. 6, electrical properties of trench capacitors 120A-120F of (i) trench capacitor group 104A can be measured from measurement structures 116A-116B, (ii) trench capacitor group 104B can be measured from measurement structures 116C-116D, (iii) trench capacitor group 104C can be measured from measurement structures 116E-116F, and (iv) trench capacitor group 104D can be measured from measurement structures 116G-116H. In another example, referring to FIG. 7, electrical properties of trench capacitors 120A-120F of (i) trench capacitor group 104A can be measured from measurement structures 216A-216B, (ii) trench capacitor group 104B can be measured from measurement structures 216C-216D, (iii) trench capacitor group 104C can be measured from measurement structures 216E-216F, and (iv) trench capacitor group 104D can be measured from measurement structures 216G-216H. In some embodiments, the electrical properties of trench capacitors 120A-120F measured from measurements structures 116A-116H can be capacitance values.

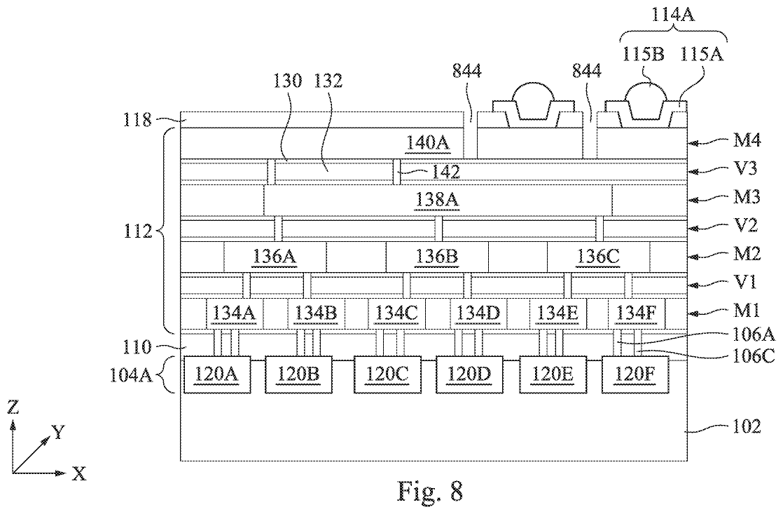

Referring to FIG. 4, in operation 330, one or more of the trench capacitors are disconnected from the bonding structures based on the measured electrical properties. For example, as shown in FIG. 8, trench capacitors 120A-120F of trench capacitor group 104A are disconnected from bonding structures 114A and 114B (not visible in FIG. 8) in response to determining the presence of a defective trench capacitor in trench capacitor group 104A based on the measured electrical properties. In some embodiments, the capacitance value measured from measurements structures 116A-116H can indicate the presence of a defective trench capacitor if the capacitance value is different from a value expected from trench capacitors 120A-120F. The disconnecting process can be performed by forming trenches 844 in regions 144 of top metal line 140A and trenches (not shown) in regions 146 of top metal line 140B. In some embodiments, the trenches in regions 144 and 146 can be formed with a laser cutting tool or with lithography and etching processes. In some embodiments, trenches 844 and trenches in regions 146 can be filled with an insulating layer 944.

Similarly, trench capacitors 120A-120F of trench capacitor groups 104B-104C can be disconnected from bonding structures 114C-114F in response to determining the presence of a defective trench capacitor in trench capacitor groups 104B-104C based on the measured electrical properties. On the other hand, trench capacitors 120A-120F of reserve trench capacitor group 104D can be disconnected from bonding structures 114G-114H in response to determining the absence of a defective trench capacitor in trench capacitor group 104D based on the measured electrical properties. In some embodiments, the capacitance value measured from measurements structures 116A-116H can indicate the absence of defective trench capacitors if the capacitance value is equal to the value expected from the trench capacitors. To disconnect trench capacitors 120A-120F of reserve trench capacitor group 104D, a disconnecting process can be performed on top metal lines 140G-140H similar to that discussed above with reference to top metal lines 140A-140B.

In some embodiments, the disconnecting process can be followed by a die singulation process performed on substrate 102 along scribe lane areas 650 and 750 to form singulated passive device dies 100 and 200. In some embodiments, the die singulation process can be performed between operation 320 and operation 325.

The present disclosure provides example structures and methods for improving the manufacturing yield of wafers having passive device dies, such as trench capacitor dies (e.g., passive device dies 100 and 200). In some embodiments, each trench capacitor die can include trench capacitors (e.g., trench capacitors 120A-120F), an interconnect structure (e.g., 112) disposed on the trench capacitors, bonding structures (e.g., 114A-114H) disposed on the interconnect structure, and measurement structures (e.g., 116A-116H and 216A-216H) disposed on the interconnect structure. The interconnect structure can be configured to provide an electrical connection between the trench capacitors and the measurement structures and between the trench capacitors and the bonding structures. The measurement structures can include conductive pads and can be configured to detect and identify the defective trench capacitors in the trench capacitor die. The bonding structures can include conductive pads (e.g., conductive pads 115A) and solder bumps (e.g., solder bumps 115B) and can be configured to electrically connect the non-defective trench capacitors to other peripheral circuits and/or integrated circuit dies. A defective trench capacitor can refer to a malfunctioning trench capacitor.

In some embodiments, the trench capacitors in each trench capacitor die can be divided into groups of trench capacitors (e.g., trench capacitor groups 104A-104D). In some embodiments, one or more of the groups of trench capacitors are formed in addition to the number of groups of trench capacitors desired for each trench capacitor die. These additional groups of trench capacitors are formed as reserve groups of trench capacitors (e.g., reserve trench capacitor group 104D), which can be used to replace one or more groups of trench capacitors that are found to be defective after the fabrication of the trench capacitor dies.

In some embodiments, each group of trench capacitors can be electrically connected to (i) a pair of metal lines in the topmost metal line layer (e.g., metal line layer M4) of the interconnect structure, (ii) a pair of bonding structures, and (iii) a pair of measurement structures. The first metal line (e.g., metal lines 140A, 140C, 140E, and 140G) of each pair of metal lines can be electrically connected to the first voltage and to the corresponding group of trench capacitors through the first and third contact structures. The second metal line (e.g., metal lines 140B, 140D, 140F, and 140H) of each pair of metal lines can be electrically connected to the second voltage and to the corresponding group of trench capacitors through the second and fourth contact structures. In some embodiments, the first and second bonding structures of each pair of bonding structures (e.g., boding structures 114A-114B, 114C-114D, 114E-114F, and 114G-114H) can be electrically connected to the first and second metal lines of each respective pair of metal lines (e.g., metal lines 140A-140B, 140C-140D, 140E-140F, and 140G-140H). In some embodiments, the first and second measurement structures of each pair of measurement structures (e.g., measurement structures 116A-116B, 116C-116D, 116E-116F, and 116G-116H) can be electrically connected to the first and second metal lines of each respective pair of metal lines.

With such configurations of the metal lines and measurement structures, the electrical properties (e.g., capacitance) of each group of trench capacitors can be extracted through the measurement structures with a test system including a probe card and a measurement apparatus. Based on the extracted electrical properties, the presence and absence of defective group(s) of trench capacitors in the manufactured trench capacitor dies can be detected and identified. In response to the detection of defective group(s) of trench capacitors, the electrical connections between the bonding structures and the defective group(s) of trench capacitors can be reconfigured to electrically disconnect the defective group(s) of trench capacitors from the bonding structures. On the other hand, in response to the absence of defective group(s) of trench capacitors, the electrical connections between the bonding structures and the reserve group(s) of trench capacitors can be reconfigured to electrically disconnect the reserve group(s) of trench capacitors from the bonding structures. As a result, trench capacitor dies with the desired number of non-defective groups of trench capacitors can be achieved and the wafer manufacturing yield can be improved.

In some embodiments, the reconfiguration of the electrical connections between the bonding structures and the defective group(s) of trench capacitors can include cutting the first and second metal lines of the corresponding defective group(s) of trench capacitors. Similarly, the reconfiguration of the electrical connections between the bonding structures and the reserve group(s) of trench capacitors can include cutting the first and second metal lines of the corresponding reserve group(s) of trench capacitors. In some embodiments, the cutting can include removing portions of the first and second metal lines using a laser cutting tool. In some embodiments, the reconfiguration process can be performed on the trench capacitor dies prior to performing a die singulation process on the wafer to separate the trench capacitor dies from each other for individually packaging the singulated trench capacitor dies. In some embodiments, the reconfiguration process can be performed on the trench capacitor dies after performing the die singulation process, but prior to individually packaging the singulated trench capacitor dies.

In some embodiments, a structure includes a substrate, first and second groups of trench capacitors disposed on the substrate, an interconnect structure disposed on the first and second groups of trench capacitors, first and second bonding structures disposed on the first and second conductive lines, respectively, and first and second measurement structures electrically connected to the first and second conductive lines, respectively, and configured to measure electrical properties of the first and second groups of trench capacitors, respectively. The interconnect structure includes a first conductive line electrically connected to the first group of trench capacitors, and a second conductive line electrically connected to the second group of trench capacitors. The first and second conductive lines are electrically isolated from each other. The first bonding structure is electrically connected to the first group of trench capacitors and the second bonding structure is electrically isolated from the first and second groups of trench capacitors. The first and second measurement structures are electrically isolated from each other.

In some embodiments, a structure includes a substrate, first and second groups of capacitors disposed on the substrate, a first conductive line connected to the first group of capacitors, and a second conductive line with first and second line portions. The first line portion is connected to the second group of capacitors. The structure further includes a first conductive structure disposed directly on the first conductive line and connected to the first group of capacitors, a second conductive structure disposed directly on the second line portion and electrically isolated from the first and second groups of capacitors, and first and second measurement structures disposed directly on the first and second conductive lines, respectively, and configured to measure electrical properties of the first and second groups of capacitors, respectively.

In some embodiments, a method includes forming first and second groups of trench capacitors in a substrate, forming a first conductive line on the first group of trench capacitors, forming a second conductive line on the second group of trench capacitors, depositing a passivation layer on the first and second conductive lines, forming a first bonding structure on the first conductive line through the passivation layer, forming a second bonding structure on the second conductive line through the passivation layer, measuring electrical properties of the first and second groups of trench capacitors, and forming a trench in the first or second conductive line based on the electrical properties of the first group of trench capacitors.

The foregoing disclosure outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A structure, comprising:
a substrate;
first and second groups of trench capacitors disposed on the substrate;
an interconnect structure disposed on the first and second groups of trench capacitors, wherein the interconnect structure comprises:
a first conductive line electrically connected to the first group of trench capacitors, and
a second conductive line electrically connected to the second group of trench capacitors, wherein the first and second conductive lines are electrically isolated from each other;
first and second bonding structures disposed on the first and second conductive lines, respectively, wherein the first bonding structure is electrically connected to the first group of trench capacitors and the second bonding structure is electrically isolated from the first and second groups of trench capacitors; and
first and second measurement structures electrically connected to the first and second conductive lines, respectively, and configured to measure electrical properties of the first and second groups of trench capacitors, respectively, wherein the first and second measurement structures are electrically isolated from each other.

2. The structure of claim 1, wherein the first and second conductive lines are in a topmost metal line layer of the interconnect structure.

3. The structure of claim 1, wherein a first portion of the second conductive line is connected to the second group of trench capacitors and a second portion of the second conductive line is connected to the second bonding structure, and
wherein the first and second portions of the second conductive line are electrically isolated from each other.

4. The structure of claim 3, wherein the first and second portions of the second conductive line are separated from each other by a trench.

5. The structure of claim 3, wherein the first and second portions of the second conductive line are separated from each other by an insulating layer.

6. The structure of claim 1, wherein each of the first and second bonding structures comprises a metal pad and a solder ball.

7. The structure of claim 1, further comprising a third measurement structure electrically connected to the first group of trench capacitors and electrically isolated from the first measurement structure, wherein the first measurement structure is connected to a first voltage and the third measurement structure is connected to a second voltage higher than the first voltage.

8. The structure of claim 7, further comprising a fourth measurement structure electrically connected to the second group of trench capacitors and electrically isolated from the second measurement structure, wherein the second measurement structure is connected to the first voltage and the fourth measurement structure is connected to the second voltage.

9. The structure of claim 1, wherein each of the first and second measurement structures comprises a metal layer.

10. The structure of claim 1, wherein each trench capacitor in the first group of trench capacitors comprises a stack of capacitors electrically connected to each other in a parallel configuration.

11. The structure of claim 1, wherein each trench capacitor in the first group of trench capacitors comprises:
first and second trenches disposed in the substrate;
a first capacitor comprising first and second conductive layers disposed in the first and second trenches; and
a second capacitor comprising the second conductive layer and a third conductive layer disposed in the first and second trenches.

12. The structure of claim 11, wherein the first bonding structure and the first measurement structure is electrically connected to the first conductive layer through the interconnect structure.

13. A structure, comprising:
a substrate;
first and second groups of capacitors disposed on the substrate;
a first conductive line connected to the first group of capacitors;
a second conductive line with first and second line portions, wherein the first line portion is connected to the second group of capacitors;
a first conductive structure disposed directly on the first conductive line and connected to the first group of capacitors;
a second conductive structure disposed directly on the second line portion and electrically isolated from the first and second groups of capacitors; and
first and second measurement structures disposed directly on the first and second conductive lines, respectively, and configured to measure electrical properties of the first and second groups of capacitors, respectively.

14. The structure of claim 13, wherein each of the first and second conductive structures comprises a metal pad and a solder ball.

15. The structure of claim 13, wherein each of the first and second measurement structures comprises a metal layer.

16. The structure of claim 1, wherein each capacitor in the first group of capacitors comprises a stack of capacitors electrically connected to each other in a parallel configuration.

17. A method, comprising:
forming first and second groups of trench capacitors in a substrate;
forming a first conductive line on the first group of trench capacitors;
forming a second conductive line on the second group of trench capacitors;
depositing a passivation layer on the first and second conductive lines;
forming a first bonding structure on the first conductive line through the passivation layer;
forming a second bonding structure on the second conductive line through the passivation layer;
measuring electrical properties of the first and second groups of trench capacitors; and
forming a trench in the first or second conductive line based on the electrical properties of the first group of trench capacitors.

18. The method of claim 17, wherein measuring the electric properties comprises forming first and second measurement structures on the first and second conductive lines, respectively.

19. The method of claim 17, wherein forming the trench in the first conductive line comprises etching a portion of the first conductive line with a laser cutting tool in response to determining a presence of a defect in the first group of trench capacitors based on the electrical properties.

20. The method of claim 17, wherein forming the trench in the second conductive line comprises etching a portion of the second conductive line with a laser cutting tool in response to determining an absence of a defect in the first group of trench capacitors based on the electrical properties.
